(19) United States
(12) Patent Application Publication
(10) Pub. No.: US 2014/0364041 A1
(43) Pub. Date: Dec. 11, 2014

(54) APPARATUS AND METHOD FOR POLISHING WAFER

(71) Applicant: LG Siltron Inc., Gyeongsangbuk-do (KR)

(72) Inventors: Sehun Choi, Gyeongsangbuk-do (KR); Kyeongsoon Kim, Gyeongsangbuk-do (KR); Youghee Mun, Gyeongsangbuk-do (KR)

(21) Appl. No.: 14/365,976

(22) PCT Filed: Dec. 14, 2012
(86) PCT No.: PCT/KR2012/010944

§ 371 Date: Jun. 16, 2014

(30) Foreign Application Priority Data
Dec. 16, 2011 (KR) 10-2011-0136428
Aug. 28, 2012 (KR) 10-2012-0094202

(51) Int. Cl. B24B 53/017; H01L 21/304; B24B 37/04

(52) U.S. Cl. CPC B24B 53/017; B24B 37/04; B24B 37/042; H01L 21/304
USPC 451/41; 451/72

(57) ABSTRACT

Provided is an apparatus for polishing a wafer. The apparatus for polishing a wafer include a surface plate, a polishing pad disposed on the surface plate, the polishing pad including a plurality of fixed polishing particles, a head part disposed on the polishing pad, a retainer mounted on an outer surface of the head part, and a dressing part mounted a lower end of the support part, the dressing part having a ring shape.

### CROSS-REFERENCE TO RELATED APPLICATIONS

The present application is a national phase application of PCT application PCT/KR2012/010944 filed Dec. 14, 2012, which claims the priority benefit of Korean patent application Korean patent application 10-2012-0094202 filed Aug. 28, 2012 and 10-2011-0136690 filed Dec. 16, 2011, the disclosures of which are incorporated herein by reference.

### BACKGROUND OF THE INVENTION

1. Technical Field

Embodiments relate to an apparatus for polishing a wafer.

2. Background Art

In a related art, disclosed are a semiconductor wafer polishing method in which both surfaces of a semiconductor wafer are polished by a polishing pad while supplying a polishing agent (DSP process) as stock removal polishing method, and a semiconductor wafer polishing method in which only a front surface (a component-side) of a semiconductor wafer is finally polished by using a softer polishing pad (CMP process, “finishing”) as a so-called haze-free polishing method and a so-called new “fixed abrasive polishing (FAP) method. In the fixed abrasive polishing (FAP) method, semiconductor wafers are polished on a polishing pad (“fixed abrasive pad”) combining a polishing material.

A polishing process using the FAP polishing pad is referred to as a FAP process. A two-stage polishing method including a first FAP polishing process and a follow-up second CMP polishing process is disclosed in International Publication Application No. WO 99/55491 A1. In case of the CMP, a polishing material is not combined in the polishing pad. Thus, like the DSP, the polishing material having a slurry form is introduced between the polishing pad and semiconductor wafers. The two-stage polishing method, particularly, the FAP process is used to remove scratches remaining in the polished surface of a substrate.

Researches for improving the flatness of a wafer are being variously carried out.

### SUMMARY OF THE PRESENTLY CLAIMED INVENTION

### Technical Problem

Embodiments provide a wafer polishing apparatus which is capable of improving flatness of a wafer and efficiently polishing wafers.

### Solution to Problem

In one embodiment, an apparatus for polishing a wafer includes: a surface plate; a polishing pad disposed on the surface plate, the polishing pad including a plurality of fixed polishing particles; a head part disposed on the polishing pad; a retainer mounted on an outer surface of the head part; and a dressing part mounted a lower end of the support part, the dressing part having a ring shape.

In another embodiment, an apparatus for polishing a wafer includes: a polishing pad to which fixed polishing particles are attached, the polishing pad being disposed on a rotatable surface; a head part rotated by a rotational shaft different from that of the surface plate, the head part being disposed above the surface plate; a retainer mounted on an outer surface of the head part; and a dressing part contacting the retainer to dress the polishing pad, wherein a portion of the wafer is mounted on the head part to protrude by a predetermined distance from an edge of the polishing pad.

### Advantageous Effects of Invention

In wafer polishing apparatus according to the embodiments, the wafer polishing or polishing pad dressing may be performed using the single apparatus.

Also, when the wafer is polished through the fixed polishing pad, the edge area of the wafer may be improved in flatness due to the overhang structure of the wafer. In addition, the polishing pad may be smoothly dressed by the dressing part.

### BRIEF DESCRIPTION OF THE DRAWINGS

FIG. 1 is a cross-sectional view of a wafer polishing apparatus according to a first embodiment.

FIG. 2 is a plan view of a wafer polishing apparatus according to the first embodiment and a second embodiment.

FIG. 3 is a view of a dressing part and a retainer according to the first and second embodiments.

FIGS. 4 and 5 are views of the retainer and the dressing part according to the first and second embodiments.

FIG. 6 is a cross-sectional view of a wafer polishing apparatus according to the second embodiment.

FIG. 7 is a view for explaining a position relationship between a wafer and a polishing pad in the wafer polishing apparatus according to the second embodiment.

### DETAILED DESCRIPTION

Embodiments A polishing apparatus which is capable of improving flatness of a side surface of a wafer when the wafer is polished and improving an edge shape of the wafer through a simple structure thereof according to the embodiments will be described in detail with reference to the accompanying drawings.

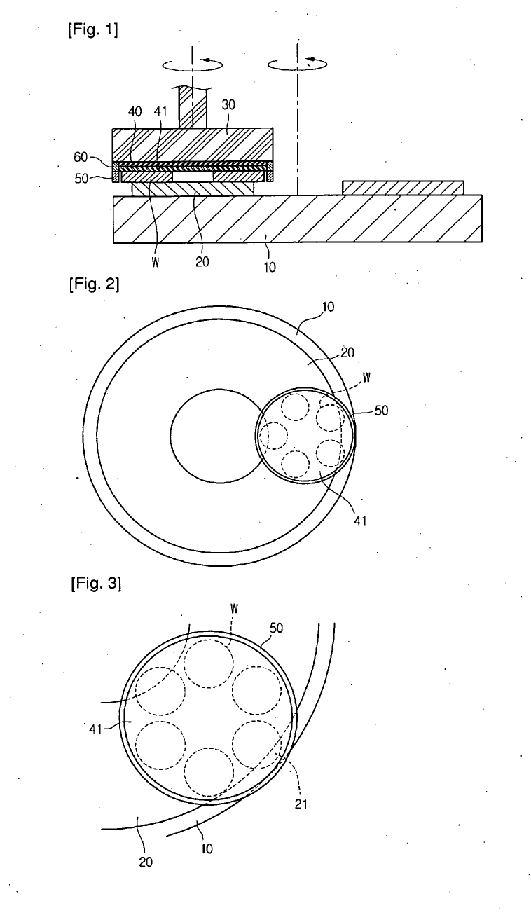

FIG. 1 is a cross-sectional view of a wafer polishing apparatus according to a first embodiment.

Referentially, a dressing part and a retainer illustrated in FIGS. 2 to 5 may be equally applied to a following second embodiment.

Referring to FIGS. 1 to 5, a wafer polishing apparatus according to a first embodiment includes a surface plate 10, a polishing pad 20, a head part 30, a ceramic plate 41, a dressing part 50, and a retainer 60.

The surface plate 10 supports the polishing pad 20, and the fixed polishing pad 20 depends on rotation of the surface plate 100. The polishing pad may be a fixed polishing pad to which fixed polishing particles are attached. The polishing pad may be formed of silicon carbide compound, boron nitride compound, diamond, or a combination thereof. Also, the surface plate 10 may be derived and rotated by a motor.

The polishing pad 20 may be fixed to a top surface of the surface plate 10. The polishing pad 20 may having a ring shape when viewed from a top side.

Also, the polishing pad 20 may be formed of a polymer or may include a plurality of fixed abrasives disposed within the polymer.

The polishing pad 20 may polish a wafer W received in the retainer 60 by using the fixed abrasives. Also, silica or alumina abrasives may be further used to assist the polishing of the wafer W.

The head part 30 is disposed spaced a predetermined distance upward from the surface plate 10. Also, the ceramic plate 41, the dressing part 50, and the retainer 60 are fixed to the head part 30.

The retainer 40 is mounted on an outer surface of the head part 30. The dressing part 50 for dressing the polishing pad is coupled to the head part 30 by the retainer 40. Thus, when the head part 30 is rotated, the retainer 40 and the dressing part 50 may be also rotated. Particularly, the dressing of the polishing pad and the polishing of the wafer may be selectively performed. That is, since the head part 30 is rotated while the surface plate 10 is rotated, the dressing of the polishing pad and the polishing of the wafer may be selectively performed.

The retainer 60 may have a size greater than that of the head part 30 and may be detached to the outer surface of the head part 30. Also, the dressing part 50 for dressing the polishing pad 20 is mounted on a lower portion of the retainer 60. When the wafer W is attached to the head part 30, the wafer is polished. On the other hand, when the wafer is not attached, the polishing pad 20 is dressed by the dressing part 50.

That is, since the rotational shafts of the head part 30 and surface plate 10 are different, the polishing pad 20 rotated together with the surface plate 10 may contact the wafer W or the dressing part 50 due to a rotational shaft difference between the head part 30 and the surface plate 10 when the head part 30 and the surface plate 10 are rotated simultaneously.

The retainer 60 has a ring shape. The retainer 60 has a diameter greater than that of the head part 30. Thus, the retainer 60 is fitted into the head part 30 to surround the outer surface of the head part 30. Also, the retainer 60 may be formed of a material such as stainless steel. The retainer 60 may directly contact the dressing part 50.

As described above, the dressing part 50 dresses the fixed polishing pad and also prevents the wafer from being separated. The dressing part 50 may be formed of a material such as alumina, but the present disclosure is not limited thereto.

Also, the ceramic plate 41 may be disposed between the wafer W and the head part 30 to fix the wafer to the head part 30 when the wafer is polished. The wafer W may be attached to the ceramic plate 41. Here, high attachment precision may be required to improve flatness of the wafer W.

Also, a back film 40 as a buffer unit may be further disposed between the head part 30 and the ceramic plate 41. The back film 40 is disposed under the head part 30 to adjust non-uniformity of a pressure applied into the wafer when the wafer is polished. FIG. 1 illustrates a state in which the wafer W is attached to the plate 41 to polish the wafer W. However, when the polishing pad is dressed, the wafer W is in a non-mounted state according to the current embodiment. While the polishing pad is dressed, the dressing part 50 surrounding the outer surface of the head part 30 contacts a top surface of the polishing pad 20 as shown in FIG. 2.

Particularly, according to the current embodiment, when the wafer is attached to the plate 41 to polish the wafer W, the wafer W may be overhung with respect to the polishing pad 20 to improve polishing flatness of an edge of the wafer. That is, as shown in FIGS. 2 to 3, the wafer W may overlap an outer circumferential portion of the polishing pad 20. Also, a portion 21 of the wafer W may be disposed further outside than the outer circumferential portion of the polishing pad 20. Accordingly, the wafer W may be disposed in an overhang structure with respect to the polishing pad 20. That is, a portion 21 of the outer circumferential portion of the wafer W may be disposed further outside than the outer circumferential portion of the polishing pad 20.

Due to the overhang disposition of the wafer, a difference between a sliding distance of the wafer W with respect to the polishing pad 20 at an edge portion of the wafer W and a sliding distance of the wafer W with respect to the polishing pad 20 at a central portion of the wafer W may be reduced. That is, the outer circumferential portion of the wafer W protrudes outwardly from an edge of the polishing pad 120 to prevent the outer circumferential portion of the wafer W from being excessively polished.

Thus, the wafer W may have a uniform sliding distance on the whole. Accordingly, when an overall uniform pressure is applied into the wafer W, the wafer W may be uniformly polished on the whole. As a result, the wafer polishing apparatus according to the current embodiment may uniformly polish the wafer W on the whole.

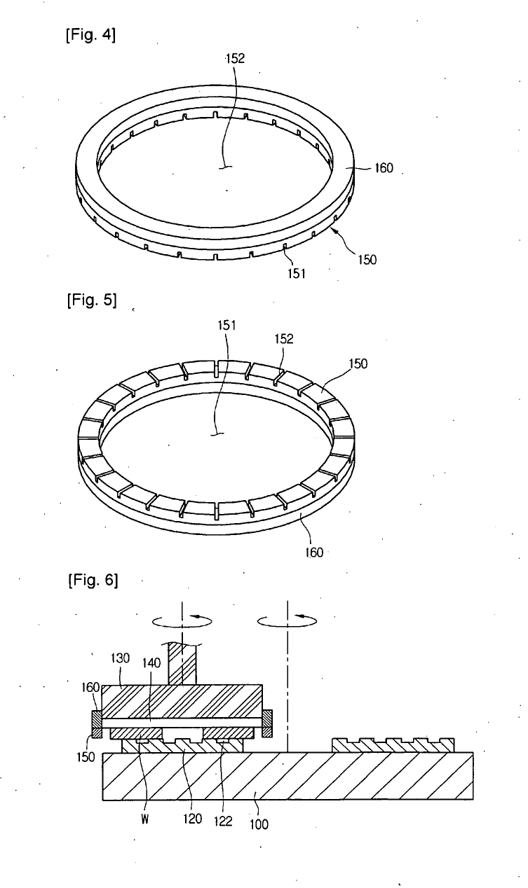

FIGS. 4 and 5 are views of the retainer and the dressing part applicable to the first and the second embodiments.

Referring to FIGS. 4 and 5, the retainer 60 and the dressing part 50 may have a closed loop shape. The closed loop shape may have a size (diameter) larger than that of a head part 30. The retainer 60 and the dressing part 50 may be coupled to an outer surface of the head part 30 through a press-fit or attachment manner.

The dressing part 50 is fixed to the head part 30 by the retainer 60. As described above, the wafer is disposed inside the retainer 60 when the wafer is polished.

The dressing part 50 directly contacts the polishing pad 20 to dress the polishing pad 20. The dressing part 50 may dress the polishing pad 20 while the wafer W is polished. For example, the dressing part 50 cuts a top surface of the polishing pad 20 to expose the fixed polishing particles.

Also, the dressing part 50 has a plurality of grooves 151. The grooves 151 may extend outward from the inside of the dressing part 50. That is, the grooves 151 may extend from an inner surface of the dressing part 50 to an outer surface or may extend outward from a center of the dressing part 50. The grooves 151 may be disposed and defined at the same distance.

The grooves 151 may be defined to pass through the dressing part 50. The dressing part 50 may be divided into plurality of blocks by the grooves 151. In other words, a plurality of the ceramic blocks may be combined with each other to constitute the dressing part 50.

The retainer 160 may have substantially the same shape as the dressing part 150. Also, the retainer 160 may be formed of stainless steel.

The wafer W may be polished using the wafer polishing apparatus through the following process according to the embodiment.

First, at least one wafer W adheres to the ceramic plate 41. The wafer W may adhere by wax.

Thereafter, the dressing part 50 and the retainer 60 are mounted on the outer surface of the head part 30. Also, the ceramic plate 41 and the wafer W are disposed inside the dressing part 50. Thereafter, the ceramic plate 41, the wafer W, the dressing part 50, and the retainer 60 are disposed on the polishing pad 20 to contact the wafer W.

Thereafter, the head part 30 descends to fix the ceramic plate 41 to the head part 30. Here, the retainer 60 and the dressing part 50 may be fixed also.

Thereafter, the wafer W is polished by the rotate of the head part 30 and the surface plate 10. Here, the wafer W may be polished in the overhang structure with respect to the polishing pad 20.

Here, a polymer remover may be used for removing a portion of a polymer of the polishing pad 20. The polymer remover may include alumina particles. Particularly, the polymer remover may be a solution in which alumina particles are dispersed into deionized water as a colloidal form. In this case, a ratio of the deionized water to alumina particle may be about 100:1 to about 80:1.

On the other hand, when the dressing is performed on the polishing pad 20 to which the fixed particles are attached, the dressing of the polishing pad may be performed by the dressing part 50 in a state where the wafer does not adhere to the plate 41.

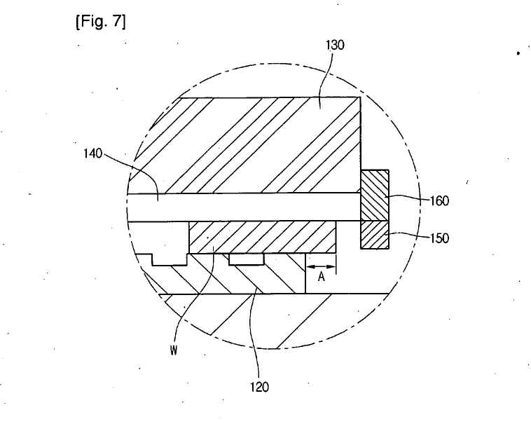

A water polishing apparatus according to a second embodiment will be described with referring to FIGS. 6 to 7. However, since a dressing part and a retainer have the same configuration and shape as those according to the first embodiment, their detailed descriptions will be referred from FIGS. 2 to 5.

Referring to FIGS. 6 to 7, a wafer polishing apparatus according to the second embodiment includes a surface plate 100, a polishing pad 120, a head part 130, a retainer 160, and a dressing part 150. A plurality of grooves may be defined in a top surface of the polishing pad 120. A bottom surface of the head part 130 contacts a ceramic plate 140. A wafer to be polished may be mounted on the ceramic plate 140.

As described above, when the wafer W is attached to the ceramic plate 140, the wafer is polished by the polishing pad 120. When the wafer W is not attached to the ceramic plate 140, the polishing pad 120 is dressed by the dressing part 150 coupled to an outer surface of the head part 130.

As described above, the polishing pad and the wafer W are disposed in the overhang structure to prevent the outer circumferential portion or edge of the wafer from being excessively polished.

Particularly, referring to FIG. 7, when the wafer is attached to the plate 140 to polish the wafer W, the wafer may be overhung with respect to the polishing pad 120 to improve polishing flatness of an edge of the wafer W. That is, as shown in FIGS. 2 to 3, the wafer W may overlap an outer circumferential portion of the polishing pad 120. Also, a portion 121 of the wafer W may be disposed further outside than the outer circumferential portion of the polishing pad 120. Accordingly, the wafer W may be disposed in the overhang structure with respect to the polishing pad 120. That is, a portion of the outer circumferential portion of the wafer W may be disposed further outside than the outer circumferential portion of the polishing pad 20.

Particularly, a portion of the wafer corresponding to a range of about 3% to about 30% with respect to a diameter of the wafer is disposed further outwardly (see reference symbol A).

Due to the overhang disposition of the wafer, a difference between a sliding distance of the wafer W with respect to the polishing pad 120 at an edge portion of the wafer W and a sliding distance of the wafer W with respect to the polishing pad 120 at a central portion of the wafer W may be reduced. That is, the outer circumferential portion of the wafer W protrudes outwardly from an edge of the polishing pad 120 to prevent the outer circumferential portion of the wafer W from being excessively polished.

Thus, the wafer W may have a uniform sliding distance on the whole. Accordingly, when an overall uniform pressure is applied into the wafer W, the wafer W may be uniformly polished on the whole. As a result, the wafer polishing apparatus according to the current embodiment may uniformly polish the wafer W on the whole.

Since embodiments can be applied to an apparatus for polishing a wafer, industrial applicability may be significantly high.

What is claimed is:

1. An apparatus for polishing a wafer, the apparatus comprising:
a surface plate;
a polishing pad disposed on the surface plate, the polishing pad comprising a plurality of fixed polishing particles;
a head part disposed on the polishing pad;
a retainer mounted on an outer surface of the head part; and
a dressing part mounted a lower end of the support part, the dressing part having a ring shape.

2. The apparatus according to claim 1, wherein the wafer is received into a bottom surface of the head part, and a portion of the wafer overlaps an outer circumferential portion of the polishing pad.

3. The apparatus according to claim 1, wherein the dressing part comprises a plurality of grooves extended outward from the inside thereof.

4. The apparatus according to claim 3, wherein distances between the grooves correspond to each other.

5. The apparatus according to claim 1, wherein the dressing part contacts directly the polishing pad.

6. The apparatus according to claim 1, wherein the wafer is received into the head part, and an outer portion of the wafer corresponding to about 3% to about 10% of a radius of the wafer protrudes outwardly from an edge of the polishing pad.

7. An apparatus for polishing a wafer, the apparatus comprising:
a polishing pad to which fixed polishing particles are attached, the polishing pad being disposed on a rotatable surface;
a head part rotated by a rotational shaft different from that of the surface plate, the head part being disposed above the surface plate;
a retainer mounted on an outer surface of the head part; and
a dressing part contacting the retainer to dress the polishing pad, wherein a portion of the wafer is mounted on the head part to protrude by a predetermined distance from an edge of the polishing pad.

8. The apparatus according to claim 7, wherein the wafer is mounted on the head part so that a portion of the wafer corresponding to about 3% to about 30% of a diameter thereof protrudes from an edge of the polishing pad.

9. The apparatus according to claim 7, wherein a plate contacting directly the wafer is further disposed between the wafer and the head part.

10. The apparatus according to claim 7, wherein the polishing pad as a fixed polishing pad is formed of one of silicon carbide compound, boron nitride compound, diamond, and a combination thereof.

11. A method for polishing a wafer by using a wafer polishing apparatus comprising a polishing pad disposed on a surface plate and containing a plurality of fixed polishing particles, a head part disposed on the polishing pad, a support part mounted on an outer surface of the head part, and a dressing part disposed on a lower end of the support part to surround the wafer to be polished, the method comprising:
polishing the wafer polished by using the polishing pad; and
dressing the polishing pad by using the dressing part.

12. The method according to claim 11, wherein the polishing of the wafer together with the dressing of the polishing pad is performed by overlapping the wafer with an outer circumferential portion of the polishing pad.
